(19) United States
(12) Patent Application Publication
(10) Pub. No.: US 2014/0011372 A1
(43) Pub. Date: Jan. 9, 2014

(54) FILM DEPOSITION METHOD

(71) Applicant: Tokyo Electron Limited, Tokyo (JP)

(72) Inventors: Hitoshi KATO, Iwate (JP); Takeshi Kumagai, Iwate (JP); Tatsuya Tamura, Iwate (JP); Hiroyuki Kikuchi, Iwate (JP)

(21) Appl. No.: 13/934,677

(22) Filed: Jul. 3, 2013

(30) Foreign Application Priority Data
Jul. 6, 2012 (JP) 2012-152111

(51) Int. Cl. H01L 21/02

(52) U.S. Cl. CPC H01L 21/02263
USPC 438/787

(57) ABSTRACT

A film deposition method deposits a silicon oxide film on a substrate in which a concave portion is formed by supplying a silicon-containing gas to the substrate so that the silicon-containing gas is adsorbed on the substrate and by oxidizing the adsorbed silicon-containing gas with an oxidation gas. A gas-phase temperature in an atmosphere above the substrate to which the silicon-containing gas is supplied can be kept lower by an inactive gas supplied from a separation area that separates the silicon gas supply part and the oxidation gas supply part even if the substrate is heated to a temperature higher than a temperature that can decompose the silicon-containing gas. Accordingly, the silicon-containing gas can adsorb on the substrate without decomposing in the gas phase.

### CROSS-REFERENCE TO RELATED APPLICATIONS

This patent application is based upon and claims the benefit of priority of Japanese Patent Application No. 2012-152111, filed on Jul. 6, 2012, the entire contents of which are incorporated herein by reference.

### BACKGROUND OF THE INVENTION

1. Field of the Invention

The present invention relates to a film deposition method that deposits a reaction product of at least two kinds of reaction gases that react with each other by alternately supplying the gases to the substrate, and more specifically to a film deposition method appropriate for filling a concave portion formed in a surface of the substrate with the reaction product.

2. Description of the Related Art

A process of fabricating a semiconductor integrated circuit (i.e., IC) includes a process of filling a concave portion formed in a surface of a substrate, such as a trench, a via hole, or a space in a line-space pattern, with silicon oxide. In filling the concave portion with the silicon oxide, a film deposition method called an atomic layer deposition (ALD) method (or molecular layer deposition (MLD) method) is preferably adopted, in which a silicon oxide film can be deposited along the concave portion (in a conformal manner). The ALD method can implement a conformal film deposition because a film made of a reaction product is deposited by allowing one source gas to be adsorbed on an inner surface of the concave portion in a (quasi-)self-limited manner first, and then by allowing the adsorbed source gas to react with the other source gas, as disclosed in Japanese Laid-open Patent Application Publication No. 2010-56470.

In filling the concave portion with the silicon oxide by the ALD method, as the silicon oxide film deposited on both side walls of the concave portion becomes thick, surfaces of the oxide film on the side walls become closer to each other, and eventually contact near the center of the concave portion, by which the concave portion is filled with the silicon oxide film. However, a contact surface (i.e., a seam) where the silicon oxide film on both side walls contacts with each other may separate from each other if the silicon oxide film on the side walls in the concave portion contracts in a heating process performed after the concave portion filling process, and may cause a void within the silicon oxide film. Moreover, in an etching process performed after the concave portion filling process, the etching may be accelerated along the seam, which may cause the void.

### SUMMARY OF THE INVENTION

Embodiments of the present invention provide a novel and useful film deposition method solving one or more of the problems discussed above.

More specifically, according to one embodiment of the present invention, there is provided a film deposition method of depositing a silicon oxide film on a substrate by exposing the substrate to a silicon-containing gas and an oxidation gas. The film deposition method includes steps of loading a substrate including a concave portion formed in a surface thereof on a turntable rotatably provided in a vacuum chamber, heating the turntable to a first temperature higher than a second temperature that can decompose a silicon-containing gas in a gas phase, and supplying an inactive gas from an inactive gas supply part provided in a ceiling surface formation part to a narrow space between the turntable and a first ceiling surface of the ceiling surface formation part. The ceiling surface formation part is provided between a first space in the vacuum chamber and a second space away from the first space in a circumferential direction of the turntable. The first ceiling surface is lower than a second ceiling surface of the first space and the second spaces. The inactive gas is supplied to at least the first space through the narrow space, thereby preventing a gas-phase temperature from increasing of the first space and preventing the silicon-containing gas from decomposing in the gas phase. The film deposition method further includes steps of supplying the silicon-containing gas to the turntable from a first gas supply part provided in the first space, supplying an oxidation gas for oxidizing the silicon-containing gas to the turntable from a second gas supply part provided in the second space, generating plasma by a plasma generation part provided between the second gas supply part and the ceiling surface formation part located on the downstream side in a rotational direction of the turntable to supply the plasma between the plasma generation part and the turntable, depositing a silicon oxide film on the substrate by rotating the turntable so that the substrate loaded on the turntable is exposed to the silicon-containing gas, the oxidation gas, and the plasma, and heating the substrate having the silicon oxide film deposited thereon.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view illustrating a film deposition apparatus preferable to implement a film deposition method of an embodiment of the present invention;

FIG. 2 is a perspective view illustrating a structure in a vacuum chamber of the film deposition apparatus in FIG. 1;

FIG. 3 is a schematic top view illustrating a structure of the vacuum chamber of the film deposition apparatus in FIG. 1;

FIG. 4 is a schematic cross-sectional view illustrating a plasma generator of the film deposition apparatus in FIG. 1;

FIG. 5 is another schematic cross-sectional view illustrating the plasma generator of the film deposition apparatus in FIG. 1;

FIG. 6 is a schematic top view illustrating the film deposition apparatus in FIG. 1;

FIG. 7 is a partial cross-sectional view of the film deposition apparatus in FIG. 1;

FIG. 8 is another partial cross-sectional view of the film deposition apparatus in FIG. 1;

FIGS. 9A through 9F are explanation drawings illustrating a film deposition method of an embodiment of the present invention;

FIG. 10 is a graph showing an etching rate of a silicon oxide film deposited by the film deposition method of an embodiment of the present invention with a comparative example and a reference example;

FIGS. 11A through 11E are scanning electron microscope images showing a cross-section of concave portions filled by an film deposition method of an embodiment of the present invention;

FIG. 12 is a graph showing a result of a silicon film deposited by the film deposition method of the embodiment of the present invention when evaluated in Fourier transform infrared spectroscopy (FTIR); and

FIG. 13 is a graph showing a measured leakage current with respect to a silicon oxide film deposited by the film deposition method of an embodiment of the present invention.

### DETAILED DESCRIPTION OF THE PREFERRED EMBODIMENTS

A description is given below, with reference to accompanying drawings of non-limiting, exemplary embodiments of the present invention. In the drawings, the same or corresponding reference marks are given to the same or corresponding members or components. It is noted that the drawings are illustrative of the invention, and there is no intention to indicate scale or relative proportions among the members or components, alone or therebetween. Therefore, the specific thickness or size should be determined by a person having ordinary skill in the art in view of the following non-limiting embodiments.

<Film Deposition Apparatus>

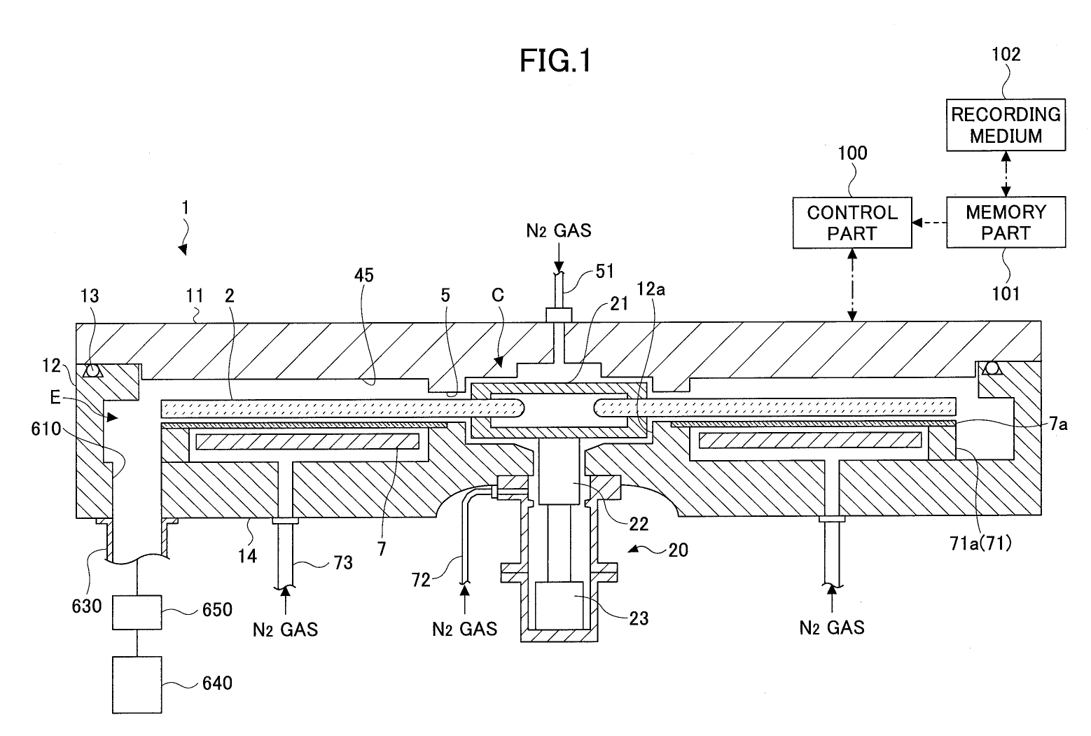

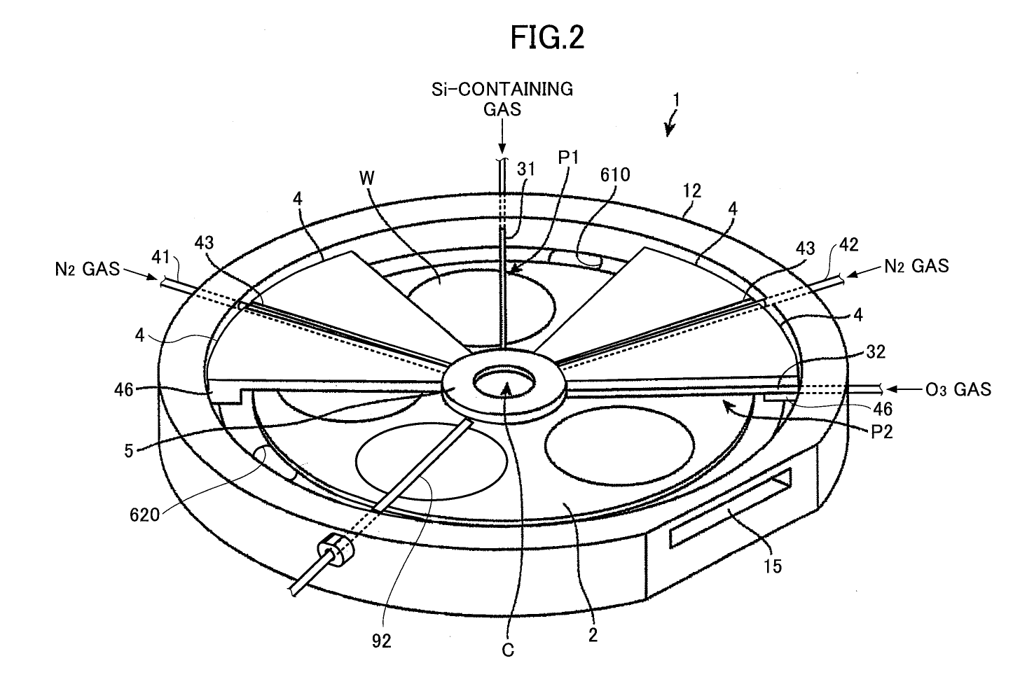

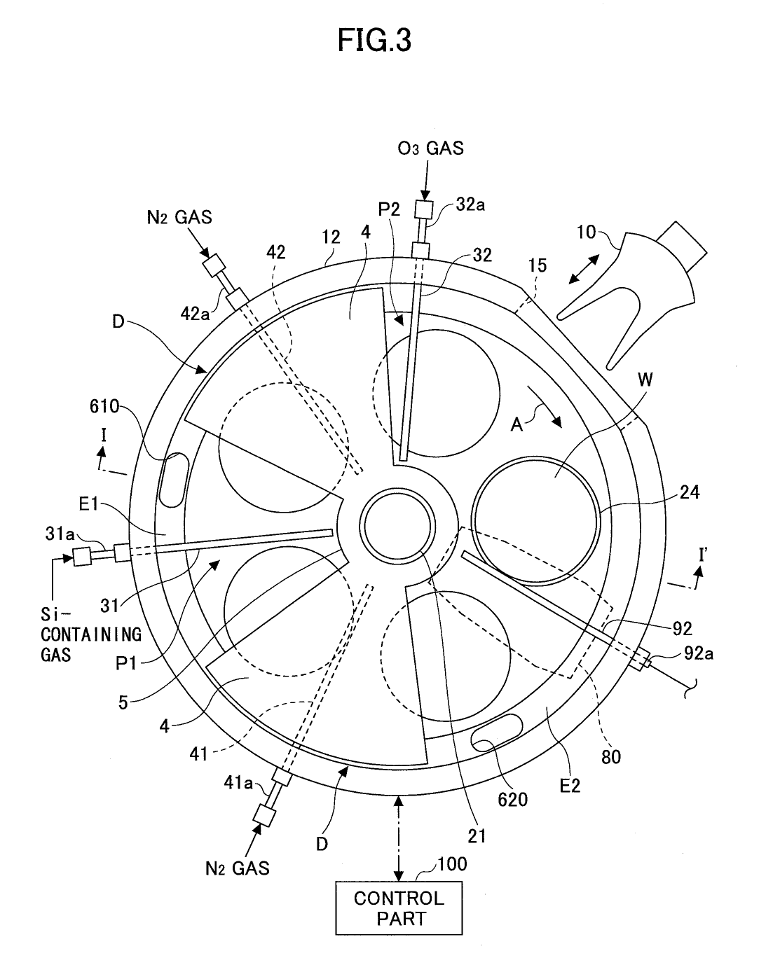

To begin with, a description is given below of a preferred film deposition apparatus to implement a film deposition method of an embodiment of the present invention. FIG. 1 is a schematic cross-sectional view of the film deposition apparatus, and FIGS. 2 and 3 are views for illustrating structures in a vacuum chamber 1. In FIGS. 2 and 3, depicting a ceiling plate 11 is omitted for convenience of explanation.

With reference to FIGS. 1 through 3, the film deposition apparatus includes a vacuum chamber 1 whose planar shape is an approximately round shape, and a turntable 2 provided in the vacuum chamber 1 and having a center of the rotation that coincides with the center of the vacuum chamber 1. The vacuum chamber 1 includes a chamber body 12 having a cylindrical shape with a bottom, and a ceiling plate 11 hermetically arranged on an upper surface of the chamber body 12 to be attachable to or detachable from the chamber body 12 through a seal member 13 (see FIG. 1) such as an O-ring.

The turntable 2 is fixed to a core portion 21 having a cylindrical shape at the center portion, and the core portion 21 is fixed to an upper end of a rotational shaft 22 that extends in a vertical direction. The rotational shaft 22 penetrates through a bottom part 14 of the vacuum chamber 1, and the lower end is attached to a drive part 23 that rotates the rotational shaft 22 (see FIG. 1) around the vertical axis. The rotational shaft 22 and the drive part 23 are housed in a cylindrical case body 20 whose upper surface is open. A flange part provided on the upper surface of this case body 20 is hermetically attached to the lower surface of a bottom part 14 of the vacuum chamber 1, by which the internal atmosphere of the case body 20 is separated from the external atmosphere.

As illustrated in FIGS. 2 and 3, a plurality of circular shaped concave portions 24 is provided to allow a plurality of (five in the example of FIG. 3) semiconductor wafers (which are hereinafter called “a wafer or wafers”) to be disposed along a rotational direction (i.e., a circumferential direction) W. In FIG. 3, the wafer W is shown in a single concave portion 24 for convenience. This concave portion 24 has an inner diameter that is slightly greater, for example, 4 mm, than a diameter of the wafer W (e.g., 300 mm), and a depth approximately equal to a thickness of the wafer. Accordingly, when the wafer W is placed on the concave portion 24, the surface of the wafer W and the surface of the turntable 2 (which means an area where the wafer is not placed) have approximately the same height.

As illustrated in FIGS. 2 and 3, above the turntable 2, a reaction gas nozzle 31, a separation gas nozzle 42, a reaction gas nozzle 32, a gas introduction gas nozzle 92, and a separation gas nozzle 41 are arranged at intervals in a circumferential direction of the vacuum chamber 1, in this order. These nozzles 31, 32, 41, 42 and 92 are introduced into the vacuum chamber 1 from an external wall by fixing gas introduction ports 31a, 32a, 41a, 42a and 92a, which are base end portions of the respective nozzles 31, 32, 41, 42 and 92 to the external wall of the chamber body 12 (see FIG. 3), and are installed such as to extend along a radial direction of the chamber body 12 and to extend parallel to the turntable 2.

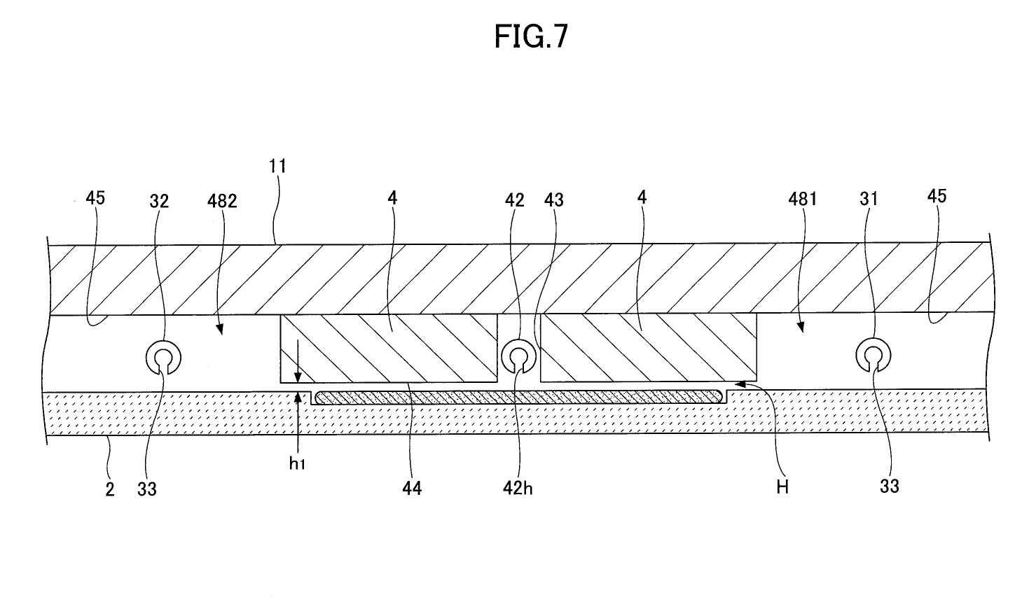

The reaction gas nozzles 31 and 32 include a plurality of gas discharge holes 33 that are open downward facing the turntable 2 (see FIG. 7) and are arranged along lengthwise directions of the reaction gas nozzles 31 and 32 at intervals of, for example, 10 mm.

As illustrated in FIG. 3, the gas introduction port 31a of the reaction gas nozzle 31 is connected to a silicon (Si) gas supply source (which is not shown in the drawing) filled with a tri(dimethylaminosilane) (Si(N(CH₃)₂)₃H, which is hereinafter expressed as 3DMAS) gas, through an on-off valve and a rate controller (both of which are not shown in the drawing). This allows the 3DMAS gas to be supplied to the wafer W loaded on the wafer loading area 24 of the turntable 2 from the reaction gas nozzle 31. The reaction gas nozzle 32 is connected to an ozone gas supply source (which is not shown in the drawing) storing an ozone gas that reacts with the silicon gas, through an on-off valve and a rate controller (both of which are not shown in the drawing). This allows the ozone gas to be supplied to the wafer W placed on the wafer loading area 24 of the turntable 2 from the reaction gas nozzle 32. Here, an area under the reaction gas nozzle 31 may be called a first process area P1 to adsorb the 3DMAS gas on the wafer W. An area under the reaction gas nozzle 32 may be called a second process area P2 to oxidize the 3DMAS gas adsorbed on the wafer W in the first process area P1.

Moreover, the separation gas nozzles 41 and 42 include a plurality of gas discharge holes 42h that are open downward facing the turntable 2 (see FIG. 7) and are arranged along lengthwise directions of the separation gas nozzles 41 and 42 at intervals of, for example, 10 mm. Furthermore, the separation gas nozzles 41 and 42 are connected to a source of an inert gas such as a noble gas including Ar or He or the like, or an N₂ gas, through an on-off valve and a rate controller (both of which are not shown in the drawing). In the present embodiment, the N₂ gas is used as the inert gas.

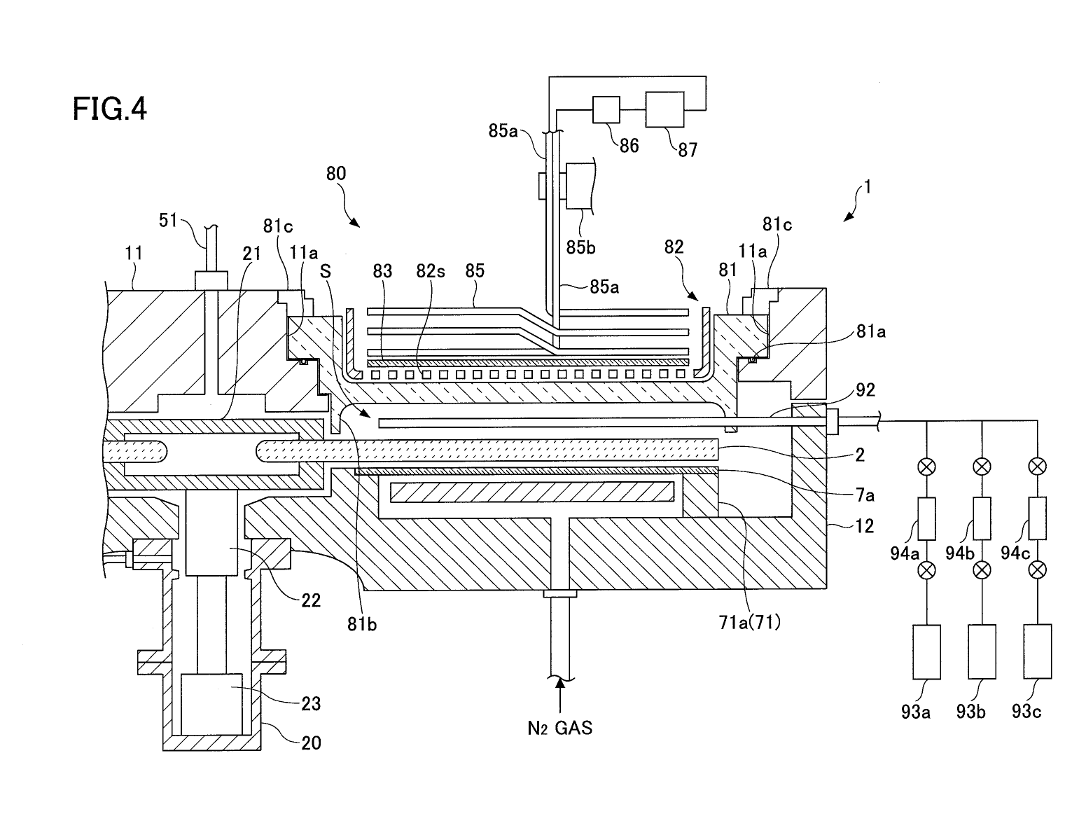

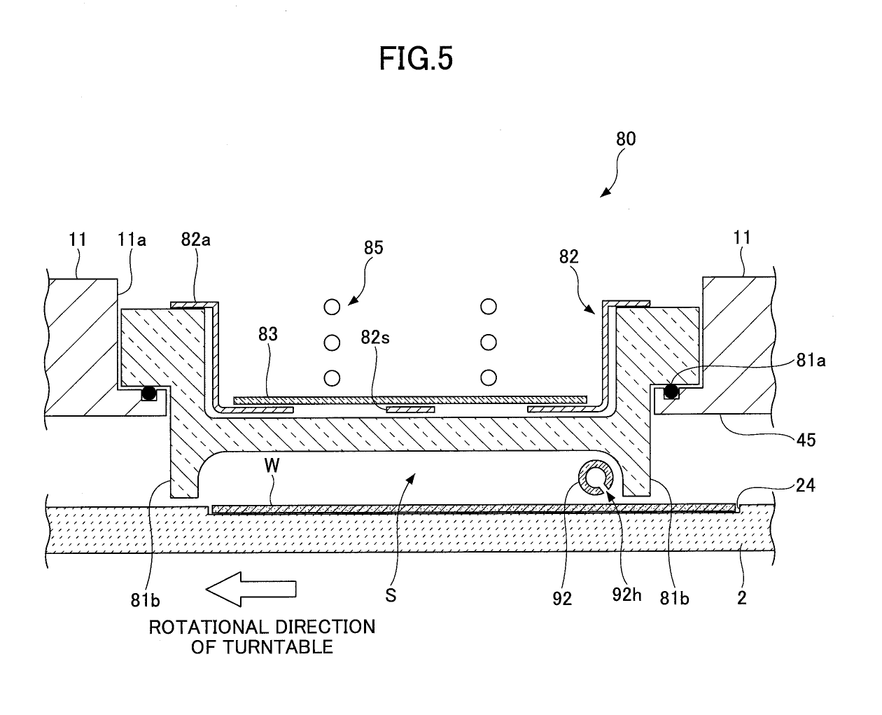

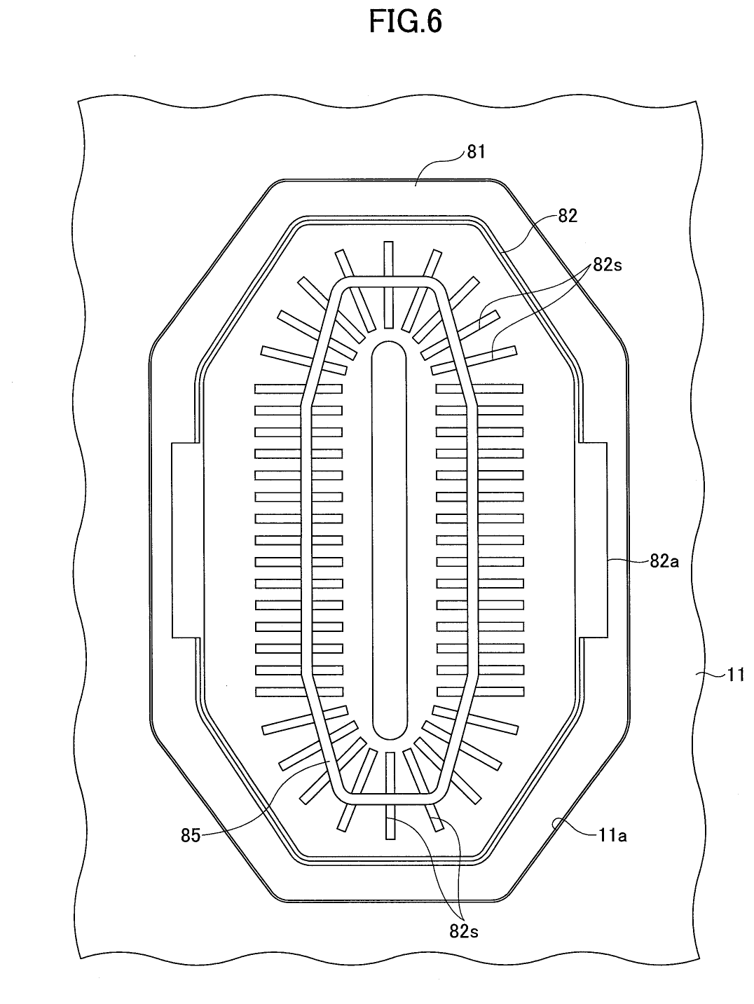

In addition, a plasma generator 80 is provided at the gas introduction nozzle 92. A description is given below of the plasma generator 80, with reference to FIGS. 4 through 6. FIG. 4 is a schematic cross-sectional view of the plasma generator 80 along a radial direction of the turntable 2. FIG. 5 is a schematic cross-sectional view of the plasma generator 80 along a direction perpendicular to the radial direction of the turntable 2. FIG. 6 is a schematic top view illustrating the plasma generator 80. Some members are simplified in these drawings for convenience of depiction.

With reference to FIG. 4, the plasma generator 80 is made of a radio frequency transmissive material, and has a concave portion recessed from the top surface. The plasma generator 80 includes a frame member 81 that is set in an opening portion 11a formed in the ceiling plate 11, a Faraday shield plate 82 having a boxy shape whose top surface is open and housed in the concave portion of the frame member 81, an insulating plate 83 disposed on a bottom surface of the Faraday shield plate 82, and a coiled antenna 85 having a top surface shape of an approximate octagon.

The opening portion 11a of the ceiling plate 11 includes a plurality of steps, and a groove portion is formed in one of the plurality of steps throughout the whole circumference, in which a sealing member 81a such as an O-ring is set. On the other hand, the frame member 81 includes a plurality of steps corresponding to the steps of the opening portion 11a. When the frame member 81a is set in the opening portion 11a, the back surface of one step contacts the sealing member 81a set in the groove portion of the opening portion 11a, by which air tightness between the ceiling plate 11 and the frame member 81 is maintained. Moreover, as illustrated in FIG. 4, a pressing member 81c is provided along the outer circumference of the frame member 81 set in the opening portion 11a of the ceiling plate 11, by which the frame member 81 is pressed down against the ceiling plate 11. By doing this, air tightness between the ceiling plate 11 and the frame member 81 is reliably maintained.

A lower surface of the frame member 81 faces the turntable 2 in the vacuum chamber 1, and an outer periphery of the lower surface includes a projection portion 81b projecting downward (i.e., toward the turntable 2) throughout the whole circumference. A lower surface of the projection portion 81b is close to the surface of the turntable 2. The projection portion 81b, the surface of the turntable 2 and the lower surface of the frame member 81 form a space (which is hereinafter called an inner space S) above the turntable 2. Here, a distance between the lower surface of the projection portion 81b and the surface of the turntable 2 may be approximately the same as a height h1 of a ceiling surface 44 relative to the upper surface of the turntable 2 in a separation area H (see FIGS. 4 and 7).

Furthermore, the gas introduction nozzle 92 that penetrates the projection portion 81b extends in the inner space S. In the present embodiment, as illustrated in FIG. 4, the gas introduction nozzle 92 is connected to an argon gas supply source 93a filled with an argon (Ar) gas, to an oxygen gas supply source 93b filled with an oxygen (O₂) gas, and to an ammonia gas supply source 93c filled with an ammonia (NH₃) gas. The Ar gas, O₂ gas and NH₃ gas, whose flow rates are controlled by corresponding flow controllers 94a, 94b and 94c, are supplied to the inner space S at a predetermined flow ratio (i.e., mixture ratio) from the argon gas supply source 93a, the oxygen gas supply source 93b and the ammonia gas supply source 93c.

In addition, the gas introduction nozzle 92 includes a plurality of discharge holes 92h formed at predetermined intervals (e.g., 10 mm) along a lengthwise direction (see FIG. 5), and the discharge holes 92h discharge the above-mentioned Ar gas and the like. As illustrated in FIG. 5, the discharge holes 92h are inclined toward the upstream side in the rotational direction of the turntable 2 relative to a direction perpendicular to the turntable 2. Because of this, the gas supplied from the gas introduction nozzle 92 is discharged toward the direction opposite to the rotational direction of the turntable 2, more specifically, to a gap between the lower surface of the projection portion 81b and the surface of the turntable 2. This prevents the reaction gas or the separation gas from flowing into the inner space S from a space under a ceiling surface 45 located on the upstream side of the plasma generator 80 along the rotational direction of the turntable 2. In addition, as discussed above, because the projection portion 81b formed along the outer periphery of the lower surface of the frame member 81 is close to the surface of the turntable 2, a pressure in the inner space S can be readily kept high due to the gas from the introduction gas nozzle 92. This also prevents the reaction gas and the separation gas from flowing into the inner space S.

The Faraday shield plate 82 is made of a conductive material such as metal, and is grounded, though the depiction is omitted in the drawing. As clearly shown in FIG. 6, a plurality of slits 82s are formed in the bottom portion of the Faraday shield plate 82. Each of the slits 82s extends so as to be approximately perpendicular to a corresponding side of the antenna 85 having a planar shape approximating an octagon.

Moreover, as illustrated in FIGS. 5 and 6, the Faraday shield plate 82 includes supporting portions 82a that are folded outward at two locations in the upper end. The supporting portions 82a are supported by the upper surface of the frame member 81, by which the Faraday shield plate 82 is supported at a predetermined position in the frame member 81.

The insulating plate 83 is made of, for example, quartz, having a size slightly smaller than the bottom surface of the Faraday shield plate 82, and is disposed on the bottom surface of the Faraday shield plate 82. The insulating plate 83 transmits radio frequency waves radiated from the antenna 85 downward while insulating the Faraday shield plate 82 from the antenna 85.

The antenna 85 is formed, for example, by triply winding a hollow pipe made of copper so as to form the approximate octagon with respect to the planar shape. Cooling water can be circulated in the pipe, which prevents the antenna 85 from being heated to a high temperature caused by the radio frequency waves supplied to the antenna 85. Moreover, as illustrated in FIG. 4, the antenna 85 includes a standing portion 85a, and a supporting portion 85b that is attached to the standing portion 85a. The supporting portion 85b serves to maintain the antenna 85 in a predetermined location within the Faraday shield plate 82. Moreover, the supporting portion 85b is connected to a radio frequency power source 87 through a matching box 86. The radio frequency power source 87 can generate radio frequency waves, for example, with 13.56 MHz.

According to the plasma generator 80 having such a configuration, when the radio frequency power source 87 supplies the radio frequency power to the antenna 85, the antenna 85 generates an electromagnetic field. An electric field component of the electromagnetic field cannot transmit downward because the electric field is blocked by the Faraday shield plate 82. On the other hand, a magnetic field component transmits into the inner space S through the plurality of slits 82s of the Faraday shield plate 82. This magnetic field component causes plasma to be generated from the gases such as the Ar gas, O₂ gas, NH₃ gas and the like supplied to the inner space S from the gas introduction nozzle 92 at the predetermined flow ratio (i.e., mixture ratio). The plasma generated in this manner can reduce irradiation damage to the thin film deposited on the wafer W or damage to respective members within the vacuum chamber 1.

With reference to FIGS. 2 and 3 again, two convex portions 4 are provided in the vacuum chamber 1. The convex portions 4 have an approximately sectorial planar shape whose apex is cut in an arc-like form. In the present embodiment, the inner arc is coupled to a protrusion portion 5 (which is described below), and the outer arc is arranged so as to be along an inner periphery of the chamber body 12 of the vacuum chamber 1. As will be noted from FIG. 7 showing a cross-sectional view of the vacuum chamber 1 along a virtual line AL concentric with the turntable 2, the convex portion 4 is attached to the back surface of the ceiling plate 11. Because of this, the low ceiling surface 44 (i.e., second ceiling surface) that is a lower surface of the convex portion 4, and the high ceiling surface 45 (i.e., first ceiling surface) higher than the ceiling surface 44, are provided in the vacuum chamber 1. In the following description, a narrow space between the low ceiling surface 44 and the turntable 2 may be called a separation space H. Furthermore, a space between the high ceiling surface 45 and the turntable 2 includes a space 481 including the reaction gas nozzle 31, and a space 482 including the reaction gas nozzle 32.

In addition, as shown in FIG. 7, a groove 43 is formed in the convex portion 4 at the center in the circumferential direction, and the groove portion 43 extends along the radial direction of the turntable 2. The groove portion 43 houses the separation gas nozzle 42. The groove portion 43 is also formed in the other convex portion 4 in a similar way, and the separation gas nozzle 41 is housed therein. When the separation gas nozzle 42 supplies an N₂ gas, the N₂ gas flows to the spaces 481 and 482 through the separation space H. At this time, because a volume of the separation space is smaller than that of the spaces 481 and 482, a pressure of the separation space H can be higher than that of the spaces 481 and 482 by the N₂ gas. In other words, the separation space H provides a pressure barrier between the spaces 481 and 482. Furthermore, the N₂ gas flowing from the separation space H to the spaces 481 and 482 is supplied to the first process area P1 and the second process area P2, and works as a counter flow against the 3DMAS gas flowing toward the convex portion 4 from the first process area P1 and the O₃ gas flowing toward the convex portion 4 from the second process area P2. Accordingly, the 3DMAS gas of the first process area P1 and the O₃ gas of the second process area P2 can be reliably separated by the separation space H. Hence, a mixture and a reaction of the 3DMAS gas and the O₃ gas in the vacuum chamber 1 are reduced.

Here, a height h1 of the ceiling surface 44 relative to the upper surface of the turntable 2 is preferably set at an appropriate height to make the pressure of the separation space H higher than the pressure of the spaces 481 and 482, considering the pressure in the vacuum chamber 1, a rotational speed of the turntable 2, and a supply amount of the separation gas (i.e., N₂ gas) to be supplied.

With reference to FIGS. 1 through 3 again, a protrusion portion 5 is provided on the lower surface of the ceiling plate 11 so as to surround an outer circumference of the core portion 21 that fixes the turntable 2. In the present embodiment, this protrusion portion 5 continuously extends to a region on the rotational center side of the convex portion 4, and the lower surface of the protrusion portion 5 is formed to be the same height as the ceiling surface 44.

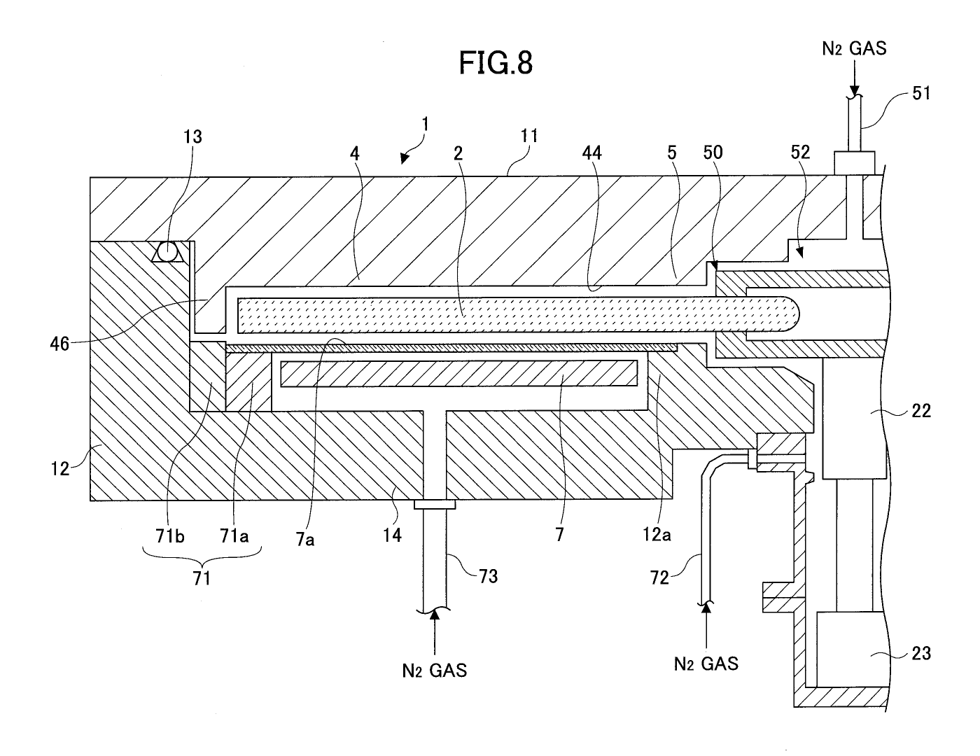

FIG. 1, which is previously referred to, is a cross-sectional view along an I-I′ line in FIG. 3, and shows an area where the ceiling surface 45 is provided. On the other hand, FIG. 8 is a partial cross-sectional view illustrating an area where the ceiling surface 44 is provided. As shown in FIG. 8, a bent portion 46 that is bent into an L-letter shape is formed in a periphery of the approximately sectorial convex portion 4 (i.e., a region on the outer edge of the vacuum chamber 1) so as to face the outer edge surface of the turntable 2. The bent portion 46 prevents a gas from circulating between the spaces 481 and 482 through a space between the turntable 2 and the inner periphery of the chamber body 12. Because the sectorial convex portion 4 is provided on the ceiling plate 11, and the ceiling plate 11 is detachable from the chamber body 12, there is a slight gap between the outer periphery of the bent portion 46 and the inner periphery of the chamber body 12. A gap between the inner periphery of the bent portion 46 and the outer edge surface of the turntable 2, and the gap between the outer periphery of the bent portion 46 and the inner periphery of the chamber body are, for example, set at a size similar to a height of the ceiling surface 44 relative to the upper surface of the turntable 2.

With reference to FIG. 3 again, a first evacuation opening 610 in communication with the space 481 and a second evacuation opening 620 in communication with the space 482 are formed between the turntable 2 and the inner periphery of the chamber body 12. As shown in FIG. 1, the first evacuation opening 610 and the second evacuation opening 620 are connected to, for example, vacuum pumps 640 of a evacuation unit through respective evacuation pipes 630. FIG. 1 also shows a pressure controller 650.

As illustrated in FIGS. 1 and 8, a heater unit 7 that is a heating unit is provided in a space between the turntable 2 and the bottom part 14 of the vacuum chamber 1, and the wafer W on the turntable 2 is heated up to a temperature determined by a process recipe (e.g., 450 degrees) through the turntable 2. A ring-shaped cover member 71 is provided on the lower side of the periphery of the turntable 2 to prevent a gas from intruding into a space under the turntable 2. As shown in FIG. 8, the cover member 71 includes an inner member 71a provided so as to face the outer edge portion of the turntable 2 and a further outer portion from the lower side, and an outer member 71b provided between the inner member 71a and the inner wall surface of the vacuum chamber 1. The outer member 71b is provided under the bent portion 46 formed in the outer edge portion of the convex portion 4 and close to the bent portion 46, and the inner member 71a is provided to surround the heater unit 7 throughout the whole circumference under the outer edge portion of the turntable 2 (and the slightly further outer portion).

As shown in FIG. 1, the bottom part 14 in a region closer to the rotational center than the space where the heater unit 7 is arranged forms a protrusion part 12a so as to get closer to the core portion 21 in the center portion of the lower surface of the turntable 2. A gap between the protrusion part 12a and the core portion 21 forms a narrow space. Moreover, a gap between an inner periphery of a through-hole of the rotational shaft 22 that penetrates through the bottom part 14 and the rotational shaft 22 is narrow, and the narrow space is in communication with the case body 20. The case body 20 includes a purge gas supply pipe 72 to supply the N₂ gas as a purge gas to the narrow space for purging the narrow space. Furthermore, a plurality of purge gas supply pipes 73 is provided at predetermined angular intervals in the circumferential direction under the heater unit 7 to purge the arrangement space of the heater unit 7 (only a single purge gas supply pipe 73 is shown in FIG. 8). In addition, a lid member 7a that covers from the inner peripheral wall of the outer member 71b (i.e., the upper surface of the inner member 71a) to the upper end of the protrusion part 12a through the circumferential direction is provided between the heater unit 7 and the turntable 2 to prevent the gas from entering the area including the heater unit 7. The lid member 7a can be made of, for example, quartz.

When the purge gas supply pipe 72 supplies an N₂ gas, this N₂ gas flows through the gap between the inner periphery of the through-hole and the rotational shaft 22, the gap between the protrusion part 12a and the core portion 21 and the space between the turntable 2 and the lid member 7a, and is evacuated from the first evacuation opening 610 or the second evacuation opening 620 (see FIG. 3). Moreover, when the purge gas supply pipe 72 supplies an N₂ gas, the N₂ gas flows out from the space including the heater unit 7 through a gap between the lid member 7a and the inner member 71a (not shown in the drawing), and is evacuated from the first evacuation opening 610 or the second evacuation opening 620 (see FIG. 3). The flows of the N₂ gas can prevent the gases in the space 481 and 482 from being mixed through the space around the center and on the lower side of the vacuum chamber 1, and through the space under the turntable 2.

Furthermore, a separation gas supply pipe 51 is connected to the central part of the ceiling plate 11 of the vacuum chamber 1, and is configured to supply an N₂ gas of the separation gas to a space 52 between the ceiling plate 11 and the core portion 21. The separation gas supplied to the space 52 is discharged toward the outer edge through a narrow space 50 between the protrusion portion 5 and the turntable 2, and along the surface of the turntable 2 on the wafer loading area side. The space 50 can be maintained at a higher pressure than that of the spaces 481 and 482 by the separation gas. Accordingly, the space 50 serves to prevent the 3DMAS gas supplied to the first process area P1 and the O₃ gas supplied to the second process area P2 from being mixed through the center area C. In other words, the space 50 (or the center area C) can function as well as the separation space H (or the separation area D).

In addition, as shown in FIGS. 2 and 3, the transfer opening 15 is formed in the side wall of the vacuum chamber 1 to transfer the wafer W, which is the substrate, between the outer transfer arm 10 and the turntable 2. The transfer opening 15 is configured to be hermetically openable and closeable by a gate valve not shown in FIGS. 2 and 3. Moreover, the wafer W is transferred between the concave portions 24, which are the wafer loading areas in the turntable 2, and the transfer arm 10 at a position where one of the concave portions 24 faces the transfer opening 15. Accordingly, lift pins for transfer to lift up the wafer W from the back side by penetrating through the concave portion 24 and the lifting mechanism (none of which are shown in the drawing) are provided at the position corresponding to the transfer position under the turntable 2.

Moreover, as shown in FIG. 1, a control part 100 constituted of a computer to control operations of the whole apparatus is provided in this film deposition apparatus, and a program to implement a film deposition process described below is stored in a memory of the control part 100. This program is constituted of instructions of step groups to cause the apparatus to implement respective operations of the apparatus, and is installed from a memory part 101 of a recording medium 102 such as a hard disk, a compact disc, a magnetic optical disc, a memory card and a flexible disc into the control part 100.

<Film Deposition Method>

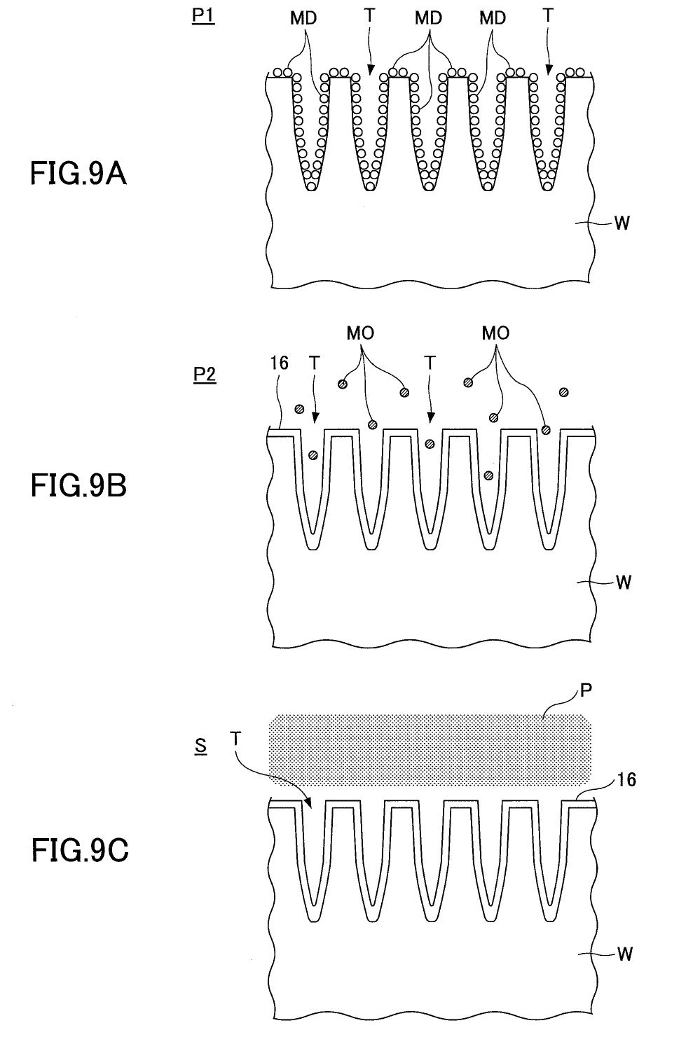

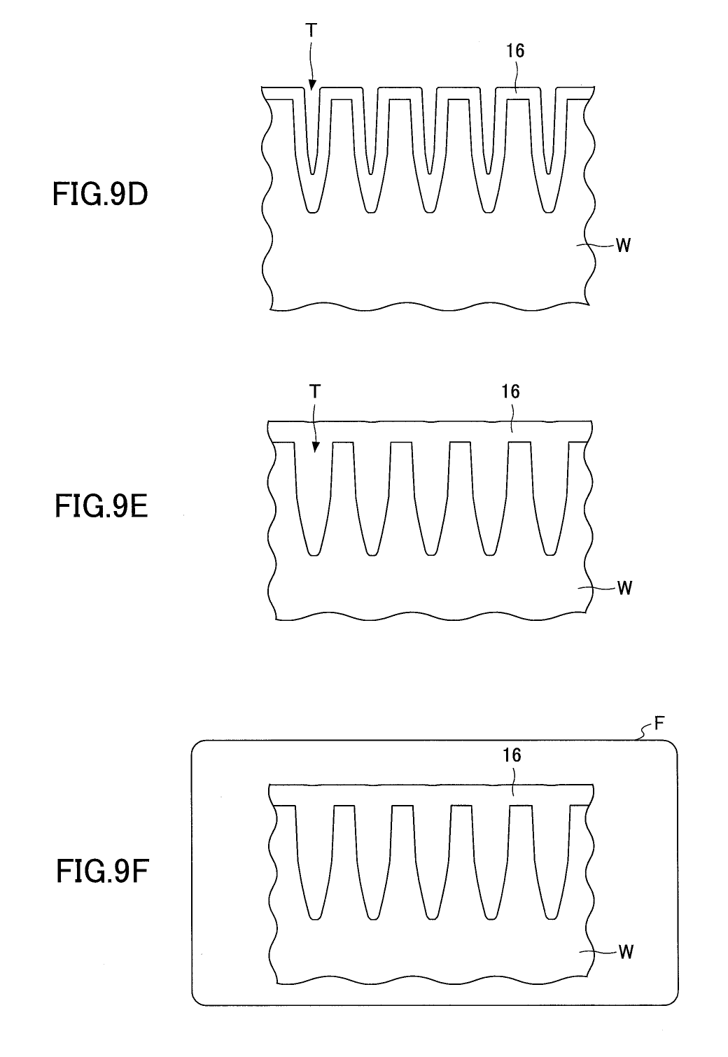

Next, a description is given of a film deposition method according to an embodiment of the present invention, which is implemented by the above-mentioned film deposition apparatus, with reference to FIGS. 9A through 9F. In the following description, a silicon wafer is assumed to be used as the wafer W, and trenches are assumed to be formed in the silicon wafer as illustrated in FIG. 9A.

<Wafer Loading>

First, agate valve not shown in the drawings is opened, and a wafer W is transferred into the vacuum chamber 1 through the transfer opening 15 (see FIGS. 2 and 3) by the transfer arm 10 (see FIG. 3), and is loaded in the concave portion 24 of the turntable 2 by the lift pins (which are not shown in the drawings). Such a transfer sequence is performed by rotating the turntable 2 intermittently, and the wafers W are each placed in the five concave portions 24 of the turntable 2.

<Condition Setting>

Next, the gate valve is closed, and the vacuum chamber 1 is evacuated by the vacuum pump 640 up to a reachable degree of vacuum. After that, the separation gas nozzles 41 and 42 supply an N₂ gas of the separation gas at a predetermined flow rate, and the separation gas supply pipe 51 and the purge gas supply pipes 72 and 73 also supply an N₂ gas of the separation gas at a predetermined flow rate. In response to this, the pressure controller 650 controls the pressure in the vacuum chamber 1 so as to become a preliminarily set process pressure. Next, the wafer W is heated, for example, up to 600 degrees by the heater unit 7, while rotating the turntable 2 in a clockwise fashion at a rotational speed of, for example, at 20 rpm.

<Deposition of Silicon Oxide Film>

Subsequently, the process gas nozzle 31 (see FIGS. 2 and 3) supplies a 3DMAS gas, and the process gas nozzle 32 supplies an O₃ gas. Also, the gas introduction nozzle 92 supplies a mixed gas of an Ar gas, an oxygen gas and an ammonia gas, and the radio frequency power source 87 supplies radio frequency waves to the antenna 85 of the plasma generator 80. In this case, the frequency of the radio frequency waves may be, for example, 13.56 MHz, and the electric power is, for example, preferably in a range from 1000 W to 10000 W.

When the wafer W reaches the first process area P1 (i.e., the area under the reaction gas nozzle 31) by rotating the turntable 2, as schematically illustrated in FIG. 9A, one molecular layer (or a couple of molecular layers) of the 3DMAS gas molecules MD is adsorbed on a surface of the wafer W or on an inner surface of trenches T. When the wafer W passes through the separation area D and reaches the second process area P2 (i.e., the area under the reaction gas nozzle 32), as schematically illustrated in FIG. 9B, the 3DMAS gas molecules MD adsorbed on the surface of the wafer W or the inner surface of the trenches T (also see FIG. 9A) are oxidized by the O₃ gas molecules MO, and a silicon oxide film 16 is deposited on the surface of the wafer W or on the inner surface of the trenches T.

Next, when the wafer W reaches a space under the plasma generator 80 (i.e., the inner space S, see FIGS. 4 and 5), as illustrated in FIG. 9C, the silicon oxide film 16 is exposed to oxygen plasma P generated by the plasma generator 80. In the oxygen plasma P, activated species such as oxygen ions, oxygen radicals or the like, or high-energy particles are generated. This attains high quality of the silicon oxide film 16 (which is described below in detail).

After that, by continuing the rotation of the turntable 2, the processes of adsorption of the 3DMAS gas, the oxidation of the 3DMAS gas, and the enhancement by the oxygen plasma are repeated, and the silicon oxide film 16 becomes thick. At this time, the silicon oxide film 16 to be deposited on the inner side surface of the trenches T is deposited so that its surfaces approach each other from both sides (see FIG. 9D). Eventually, the surfaces of the silicon oxide film 16 on both sides contact with each other, and the trenches T are filled with the silicon oxide film 16 (see FIG. 9E).

<Unloading of Wafer W>

After the trenches T of the wafer W are filled with the silicon oxide film 16, by stopping the supply of the 3DMAS gas and the O₃ gas, the film deposition of the silicon oxide film 16 is finished. After decreasing the temperature of the wafer W, the wafer W is carried out of the vacuum chamber 1 by a procedure reverse to the loading procedure of the wafer W.

<Anneal Process>

Next, as shown in FIG. 9F, the wafer W carried out of the vacuum chamber 1 is carried into, for example, a vertical-type annealing furnace F, and is annealed at a temperature, for example, in a range from 800 degrees to 1200 degrees in an inactive gas atmosphere or in an oxygen gas atmosphere for a predetermined time period. After cooling the wafer W, the wafer W is taken out of the anneal furnace F, and the film deposition method of the present embodiment is finished.

Subsequently, a description is given below of advantages of the film deposition method of the present embodiment.

As discussed above, the turntable 2 is set at a temperature such as 600 degrees. In this case, because the N₂ gas (i.e., separation gas) in the space 481 or the 3DMAS gas is heated by the turntable 2, a gas-phase temperature (i.e., a temperature of a gas in a gas phase) in the space 481 can be increased up to a temperature close to the predetermined temperature 600 degrees. For example, as disclosed in paragraph 0021 of Japanese Laid-Open Patent Application Publication No. 6-132276, it is known that the silicon oxide film can be deposited at a low deposition temperature such as about 400 degrees when using the 3DMAS gas and the oxygen gas. According to this, when the gas-phase temperature is close to 600 degrees, the 3DMAS gas may be thought to be decomposed in the gas phase. If the 3DMAS gas is decomposed in the gas phase, the atomic layer deposition cannot be implemented. Moreover, the 3DMAS gas decomposed in the gas phase can be deposited on an inner wall of the vacuum chamber 1, and can be a particle generation source.

However, in the above film deposition apparatus that practices the film deposition method of the embodiment of the present invention, the gas-phase temperature of the space 481 and the first process area P1 does not become high enough to be able to decompose the 3DMAS. This is probably because the separation gas supplied from the separation gas nozzle 41 to the separation space H flows into the space 481 without being heated sufficiently by the turntable 2, and prevents the gas-phase temperature in the space 481 and the first processing area P1 from increasing. When the increase of the gas-phase temperature is suppressed, the 3DMAS gas can reach the surface of the wafer W without decomposing in the gas phase, and can be adsorbed on the surface of the wafer W, having a thickness of one molecular layer (or a few molecular layers).

Here, one of the reasons why the adsorption of the 3DMAS gas on the wafer W is accelerated is that the 3DMAS gas can reach the turntable 2 (wafer W) before receiving thermal energy sufficient for decomposition from the turntable 2 because the reaction gas nozzle 31 is close to the surface of the turntable 2.

It is thought that the 3DMAS gas adsorbed on the surface of the wafer W is decomposed by the heat from the wafer W and that silicon atoms are deposited on the surface of the wafer W. Because these silicon atoms are oxidized by the ozone gas supplied from the reaction gas nozzle 32, when the wafer W passes the second process area P2, a silicon oxide layer having a thickness of one molecular layer (or a few molecular layers) is deposited. Furthermore, a part of the 3DMAS adsorbed on the surface of the wafer W can remain undecomposed without being thermally decomposed, but is oxidized by the ozone gas, by which the silicon oxide is generated.

Here, the temperature of the turntable 2 can become lower than the preset temperature by the separation gas. As a result of actual measurement, it is found that the actual temperature of the turntable 2 is about 570 degrees relative to the preset temperature of 600 degrees. In other words, the temperature of the turntable 2 is only about 30 degrees lower than the preset temperature, and the silicon oxide film can be said to be deposited at a temperature higher than, for example, a temperature of about 400 degrees or 450 degrees.

In addition, according to the film deposition method of the embodiments of the present invention, a high-quality silicon oxide film containing only a small amount of mixed water can be deposited because a film deposition at a relatively high temperature is possible. Because hydrogen is contained in a molecule of the 3DMAS, the silicon oxide generated from the 3DMAS gas oxidized with the O₃ gas can contain water. However, due to the relatively high deposition temperature, the amount of mixed water can be reduced.

Moreover, when the amount of mixed water is reduced, contraction of the silicon oxide film in an annealing process performed later is also reduced. In general, when the silicon oxide film filled in a gap formed in the wafer W contracts, a void may be formed along the seam in the silicon oxide in the gap. However, according to the film deposition method of the present embodiments, the formation of the void along the seam can be reduced because the contraction of the silicon oxide can be reduced.

Furthermore, when the film deposition temperature is relatively high, because adsorption coefficient of the 3DMAS to the surface of the wafer W or the inner surface of the concave portion gas is likely to grow, the 3DMAS gas readily adsorb on the surfaces with approximately only one molecular layer. In other words, there is an advantage of readily depositing a more conformal silicon oxide film.

In addition, after the 3DMAS gas adsorbed on the surface of the wafer W or the inner surface of the concave portion is oxidized by the O₃ gas in the second process area P2, and the silicon oxide film 16 is generated, because the silicon oxide film 16 is exposed to the oxygen plasma in the space under the plasma generator 80, the silicon oxide film 16 is enhanced by the activated species or the high energy particles within the plasma. More specifically, an organic substance remaining in the silicon oxide film 16 is oxidized by the activated species such as the oxygen ions, the oxygen radicals or the like, and is released outward from the silicon oxide film 16. This can reduce impurities in the silicon oxide film 16.

Moreover, the silicon atoms or the oxygen atoms in the silicon oxide film 16 receives high energy from the high energy particles that have collided with the surface of the silicon oxide film 16, and can vibrate and be rearranged. Because of this, the silicon oxide film 16 can become high quality.

Furthermore, the water in the silicon oxide film 16 can be released from the silicon oxide film 16 by the high energy received from the high energy particles.

In other words, by exposing the silicon oxide film 16 deposited on the wafer W to the plasma generated by the plasma generator 80, the silicon oxide film 16 is more unlikely to contract. Accordingly, the concern about the void generated along the seam can be further reduced in a subsequent heating process.

In addition, because the silicon oxide film 16 is annealed in a temperature range, for example, from 800 degrees from 1200 degrees, the densification of the silicon oxide film 16 is caused more and more, and a more high-quality silicon oxide film can be obtained. Here, as discussed above, because the amount of water mixed in the silicon oxide film 16 is small, the silicon oxide film 16 does not contract enough to form the void along the seam of the silicon oxide film 16.

Next, a description is given below of experiments performed to confirm advantages of the film deposition method of the embodiments of the present invention and of results of the experiments.

### First Experiment

To begin with, a description is given of a first experiment that studied an etching rate of a silicon oxide film deposited in accordance with the above-mentioned film deposition method. In the experiment, etching rates of silicon oxide films deposited in a variety of conditions were also studied for comparison, by respectively using radio frequency power supplying to the plasma generator 80 and an anneal temperature as parameters. Moreover, in the present experiment, a wafer without a concave portion was used, and a silicon oxide film was deposited on the whole surface of the wafer. In etching, an etchant in which a ratio of hydrofluoric acid solution (volume percent) to pure water was equal to 1 to 100 was used. By immersing the wafer in the etchant at a room temperature for one minute, the etching of the silicon oxide film was performed.

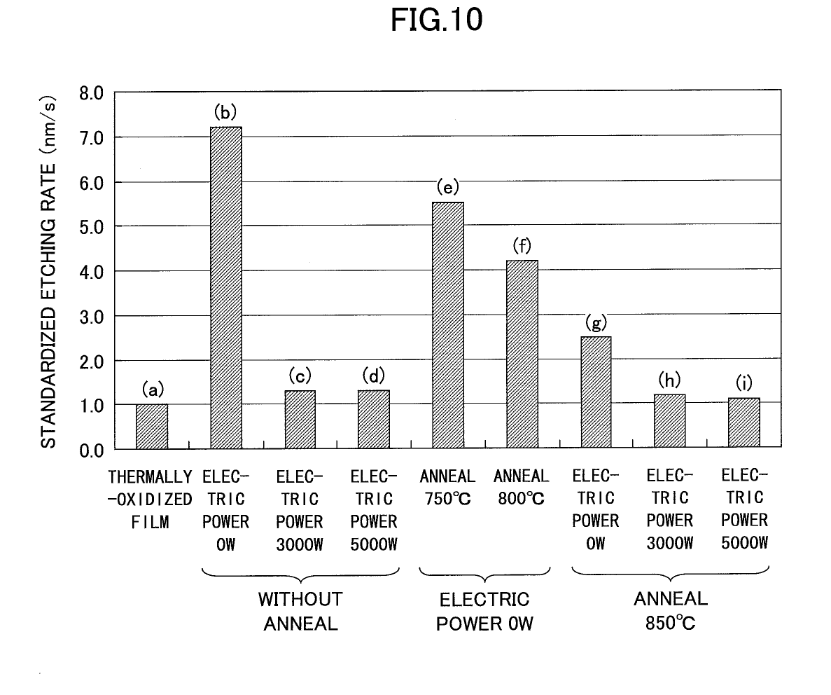

FIG. 10 is a graph showing etching rates standardized by an etching rate of a thermally-oxidized film. As shown by (a) and (b) in FIG. 10, an etching rate of a silicon oxide film obtained by depositing a silicon oxide film without exposing the silicon oxide film to oxygen plasma (i.e., electric power 0 W) and without annealing was about seven times as high as an etching rate of the thermally-oxidized film. However, in a silicon oxide film exposed by oxygen plasma generated by radio frequency power of 3000 W (which is expressed by (c) in FIG. 10) and a silicon oxide film exposed by oxygen plasma generated by radio frequency power of 5000 W (which is expressed by (d) in FIG. 10), the etching rates were only 1.3 times as high as the thermally-oxidized film. From the results, the effect of oxygen plasma radiation can be understood.

Furthermore, by comparing the result shown by (b) and results shown by (e), (f) and (g) in FIG. 10, it is noted that the etching rate is decreased by performing annealing. In addition, with reference to the results shown by (e), (f) and (g), it is noted that the higher the anneal temperature becomes, the lower the etching rate becomes, and that the etching rate is decreased up to about 2.5 times as high as the etching rate of the thermally-oxidized film particularly in the silicon oxide film annealed at 850 degrees (which is shown by (g)).

In addition, as shown by (h) in FIG. 10, an etching rate of a silicon oxide film exposed to oxygen plasma generated by radio frequency power of 3000 W and annealed at 850 degrees during the deposition was about 1.2 times as high as the etching rate of the thermally-oxidized film. Also, as shown by (i) in FIG. 10, an etching rate of a silicon oxide film exposed to oxygen plasma generated by radio frequency power of 5000 W and annealed at 850 degrees during the deposition was only about 1.1 times as high as the etching rate of the thermally-oxidized film. Moreover, these etching rates were clearly lower than the etching rates of the other silicon oxide films deposited in the other conditions in FIG. 10. From the results, the effect of the film deposition method of the embodiments of the present invention can be understood.

### Second Experiment

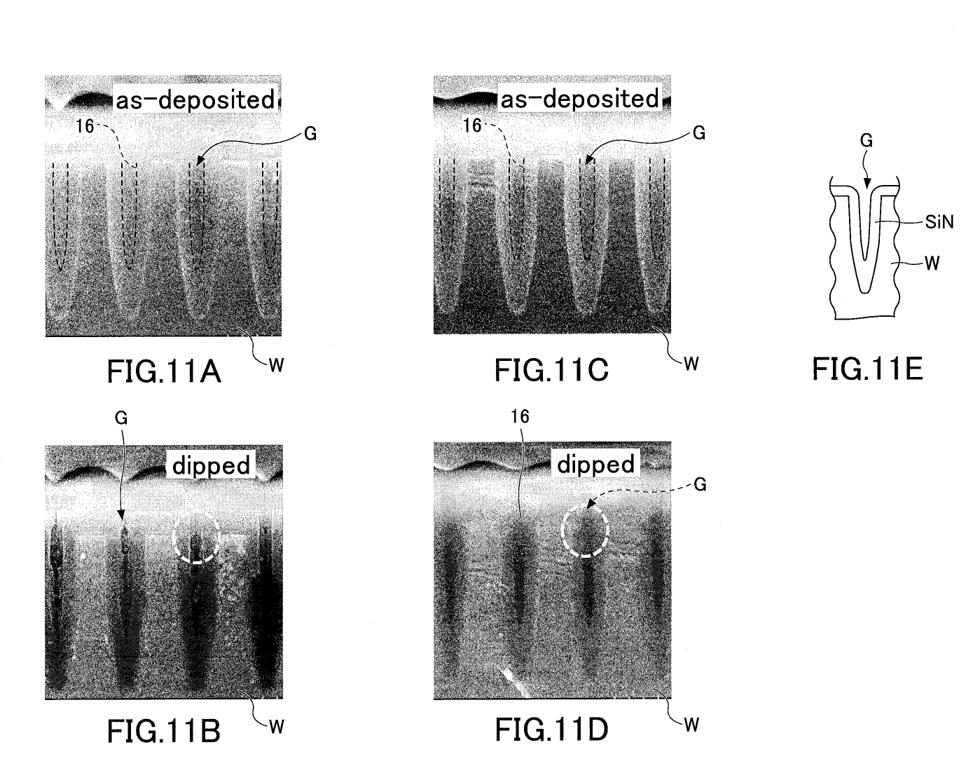

Next, properties of a silicon oxide film were studied that was filled in trenches formed in a wafer by being deposited according to the above-mentioned film deposition method. In this experiment, by depositing a silicon nitride film on the inner surface of the trenches by using the above-mentioned film deposition apparatus, a narrow gap G shown in FIG. 11E was formed, and the narrow gap G was filled with the silicon oxide film according to the above-mentioned film deposition method.

FIGS. 11A through 11E are scanning electron microscope (SEM) images and a depiction thereof that show cross-sectional views of trenches (i.e., gaps G) filled with the silicon nitride film 16. In FIG. 11A, the gaps G were exposed to the oxygen plasma generated by radio frequency power of 5000 W, and were filled with the silicon oxide film 16 that were not annealed during the deposition process. As shown in FIG. 11A, it is noted that the gaps G were filled with the silicon oxide film 16 without forming a void. FIG. 11B is a SEM cross-sectional image of the gaps after the wafer W, on which the silicon oxide film was formed under the same conditions as that of the silicon oxide film 16 shown in FIG. 11A, was etched by a fluorine-based etchant, similarly to the above. As shown in FIG. 11B, it is noted that the silicon oxide film filling in the gaps G was etched, and the voids were created.

On the other hand, in FIG. 11C, the gaps G were exposed to the oxygen plasma generated by radio frequency power of 5000 W, and were filled with a silicon oxide film 16 annealed at 1000 degrees during the deposition process. In this case, even after etching similarly to the above, a void was not formed in the gaps G. From the above results, the densification of the silicon oxide film is inferred to be caused by annealing.

### Third Experiment

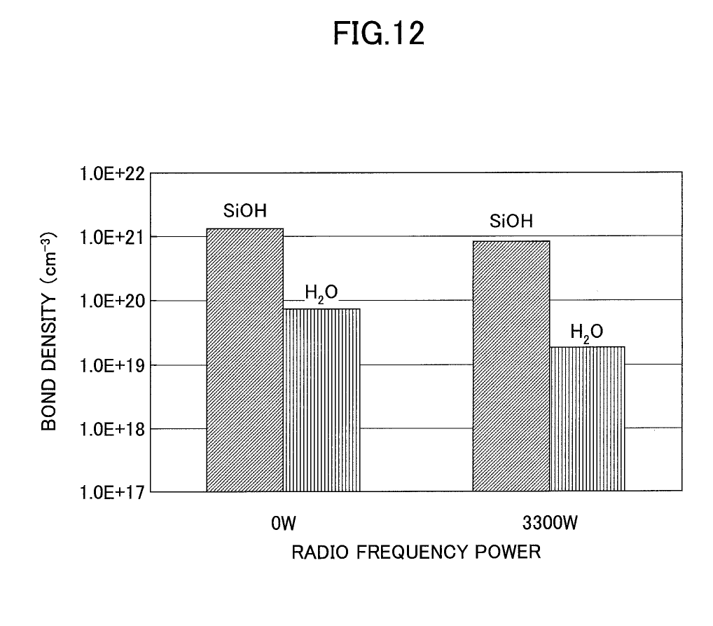

Subsequently, a description is given below of a result of evaluation of a silicon oxide film deposited according to the above-mentioned film deposition method by Fourier transform infrared spectroscopy (FTIR). FIG. 12 is a graph showing a density of an H—O bond in SiOH and a density of an H—O bond in H₂O. As shown in FIG. 12, it is noted that when the silicon oxide film was irradiated with the oxygen plasma (whose radio frequency power was 3300 W) during the film deposition process, the H—O bond was decreased compared to a case without being irradiated with the oxygen plasma (i.e., 0 W) during the film deposition process. In other words, it is thought that the H atoms in the silicon oxide film were decreased by being irradiated with the oxygen plasma, and as a result, that the silicon oxide film containing a decreased amount of mixed water was obtained.

### Fourth Experiment

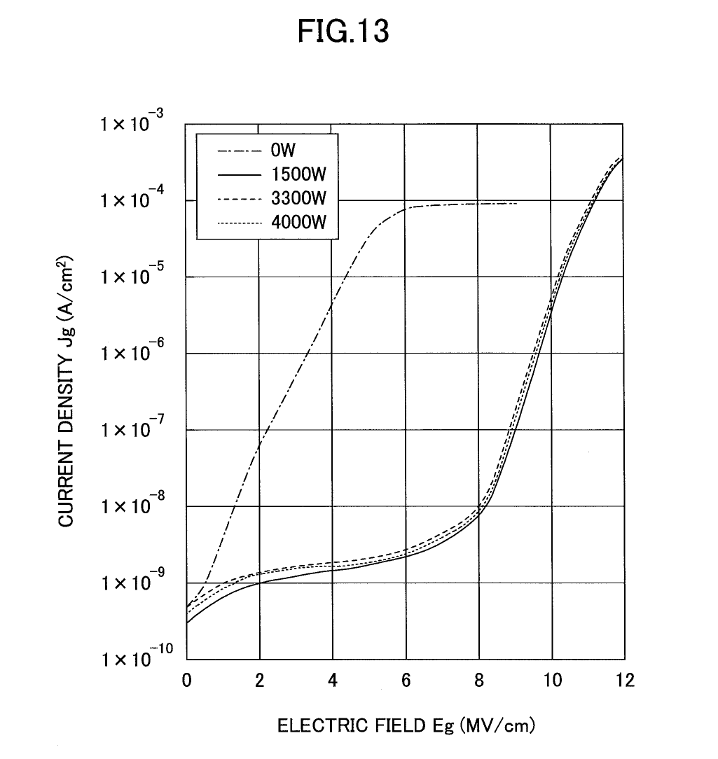

Next, a description is given below of current-voltage (electric field) properties in the silicon oxide film deposited according to the above-mentioned film deposition method. As shown in FIG. 13, it is noted that a silicon oxide film deposited without being irradiated with the oxygen plasma (0 W) during the deposition process allowed a larger current to flow than silicon oxide films deposited by being irradiated with the plasma generated by the radio frequency power of 1500 W, 3300 W and 4000 W. In other words, by being irradiated with the oxygen plasma, a high-quality silicon oxide film having a low leakage current can be obtained. Moreover, a substantial change could not be found in current-voltage properties even when the radio frequency power to generate the plasma varied from 1500 W to 3300 W, and 4000 W. From the results, with respect to the leakage current, it is noted that even the radio frequency power of a degree of 1500 W can have an effect of reducing the leakage current.

As discussed above, the embodiments and working examples of the present invention have been described in detail, it should be understood that various changes, substitutions, and alterations could be made hereto without departing from the spirit and scope of the invention.

For example, a temperature of 600 degrees is illustrated as the temperature of the turntable 2 during the deposition process of the silicon oxide film, but the temperature is not limited to this. When using the 3DMAS gas, typically, the silicon oxide film can be deposited by setting the film deposition temperature in a range from 350 to 450 degrees. In contrast, in the embodiments of the present invention, the film deposition temperature is set in a temperature range from 450 to 650 degrees. In other words, the temperature of the turntable 2 (i.e., film deposition temperature) is preferably set at a temperature about 100 to about 200 degrees higher than a temperature that can deposit the silicon oxide film by using the 3DMAS gas (e.g., 350 to 450 degrees).

Here, when the 3DMAS gas is utilized, the silicon oxide film cannot be deposited at a low temperature, for example, from 200 to 300 degrees, and the film deposition temperature need to be set at a temperature range from 350 to 450 degrees.

Furthermore, another organic silicon compound that allows an atomic layer deposition may be used instead of the 3DMAS gas. Even in this case, with respect to the organic silicon compound gas that allows the deposition of the silicon oxide film, for example, even in a range from 400 to 450 degrees, the film deposition temperature is preferably set in a temperature range from about 450 to about 550 degrees.

In addition, although the above-mentioned plasma generator 80 is a so-called induction coupled plasma (ICP) generator having the antenna 85, a capacitive coupled plasma (CCP) generator is available that generates plasma by applying radio frequency waves between two rod electrodes that extend parallel to each other. Even the CCP generator can exert the above-described effects because the CCP generator can also generate the oxygen plasma.

Moreover, the oxidation gas supplied from the reaction gas nozzle 32 is not limited to the O₃ gas, and for example, an O₂ (oxygen) gas or a mixed gas of O₂ and O₃ can be used.

Furthermore, the film deposition method according to embodiments of the present invention can be applied not only to a case of depositing a film on an inner surface of a trench but also to a case of depositing a film on a surface of a space in a line-space pattern, an inner surface of a via hole, a trench via or the like, or filling the film in the via hole, the trench via or the like.

According to embodiments of the present invention, there is provided a film deposition method that can prevent a void along a seam of a silicon oxide film filled in a concave portion formed in a substrate.

All examples recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention.

What is claimed is:

1. A film deposition method of depositing a silicon oxide film on a substrate by exposing the substrate to a silicon-containing gas and an oxidation gas, the film deposition method comprising steps of:
loading a substrate including a concave portion formed in a surface thereof on a turntable rotatably provided in a vacuum chamber;
heating the turntable to a first temperature higher than a second temperature that can decompose a silicon-containing gas in a gas phase;
supplying an inactive gas from an inactive gas supply part provided in a ceiling surface formation part to a narrow space between the turntable and a first ceiling surface of the ceiling surface formation part, the ceiling surface formation part being provided between a first space in the vacuum chamber and a second space away from the first space in a circumferential direction of the turntable, the first ceiling surface being lower than a second ceiling surface of the first space and the second spaces, the inactive gas being supplied to at least the first space through the narrow space, thereby preventing a gas-phase temperature from increasing of the first space and preventing the silicon-containing gas from decomposing in the gas phase;
supplying the silicon-containing gas to the turntable from a first gas supply part provided in the first space;
supplying an oxidation gas for oxidizing the silicon-containing gas to the turntable from a second gas supply part provided in the second gas supply space;
generating plasma by a plasma generation part provided between the second gas supply part and the ceiling surface formation part located on the downstream side in a rotational direction of the turntable to supply the plasma between the plasma generation part and the turntable;
depositing a silicon oxide film on the substrate by rotating the turntable so that the substrate loaded on the turntable is exposed to the silicon-containing gas, the oxidation gas, and the plasma; and
heating the substrate having the silicon oxide film deposited thereon.

2. The film deposition method as claimed in claim 1, wherein a volume of the narrow space is smaller than a volume of the first space.

3. The film deposition method as claimed in claim 1, wherein the silicon-containing gas is a tris(dimethylamino)silane gas.

4. The film deposition method as claimed in claim 3, wherein the first temperature is in a range from 450 to 650 degrees.

5. The film deposition method as claimed in claim 1, wherein the silicon oxide film formed on the substrate is heated at a temperature in a range from 800 to 1200 degrees.

6. The film deposition method as claimed in claim 1, wherein the plasma is generated from a gas containing an inactive gas and an oxygen gas.

7. The film deposition method as claimed in claim 1, wherein radio frequency power to generate the plasma is in a range from 1000 to 10000 W.
